(19) United States
(12) Patent Application Publication
(10) Pub. No.: US 2019/0207010 A1
(43) Pub. Date: Jul. 4, 2019

(54) SILICIDE BLOCK INTEGRATION FOR CMOS TECHNOLOGY

(71) Applicant: Texas Instruments Incorporated, Dallas, TX (US)

(72) Inventors: Binghua Hu, Plano, TX (US); Michael Allen Ball, Richardson, TX (US); Jarvis Benjamin Jacobs, Murphy (IN); James Robert Todd, Plano, TX (US)

(73) Assignee: Texas Instruments Incorporated, Dallas, TX (US)

(21) Appl. No.: 15/859,492

(22) Filed: Dec. 30, 2017

(51) Int. Cl. H01L 29/66; H01L 21/265; H01L 29/167; H01L 21/8238; H01L 29/10; H01L 21/02; H01L 29/45; H01L 21/285; H01L 21/3213; H01L 21/762; H01L 29/417; H01L 29/06; H01L 29/08; H01L 27/092

(52) U.S. Cl. CPC H01L 29/665; H01L 29/0649; H01L 29/167; H01L 21/823814; H01L 29/1095; H01L 21/823871; H01L 21/02164; H01L 29/456; H01L 21/28518; H01L 21/32137; H01L 21/823878; H01L 21/76224; H01L 29/4175; H01L 29/0688; H01L 29/0847; H01L 21/76202; H01L 27/092; H01L 21/26513

(57) ABSTRACT

An integrated circuit having silicide block integrated with CMOS transistors is formed by forming a silicide block layer of primarily silicon dioxide, free of silicon nitride and silicon oxy-nitride, at less than 400° C. prior to annealing the PMOS sources and drains. A spike anneal process concurrently anneals the PMOS sources and drains and densifies the silicide block layer. The NMOS drain junctions are less than 120 nanometers; the NMOS halo regions include boron. The NMOS and PMOS transistors are laterally separated by an STI oxide layer. A wet deglaze process prior to metal silicide formation removes less than 25 percent of the silicide block layer, and exposes sides of the NMOS drains less than 20 percent of the drain junction depth. The metal silicide does not extend down the NMOS drains sides, directly adjacent to the STI oxide layer, more than 20 percent of the drain junction depth.

### FIELD

This disclosure relates to the field of integrated circuits. More particularly, this disclosure relates to metal silicide in integrated circuits.

### BACKGROUND

An integrated circuit may include logic circuits and analog circuits. The logic circuits may have complementary metal oxide semiconductor (CMOS) gates, that is, gates of n-channel metal oxide semiconductor (NMOS) transistors and p-channel metal oxide semiconductor (PMOS) transistors. To reduce the size and fabrication cost of the integrated circuit, it is desirable to shrink the NMOS transistors and PMOS transistors in the logic circuits. Metal silicide, formed by a self-aligned process, is commonly formed on sources and drains of the NMOS transistors and PMOS transistors to reduce electrical resistances of the transistors and thus improve the operating speed of the logic circuits. One or more of the analog circuits may include components having a silicide block layer, which is a patterned dielectric layer over silicon that blocks formation of the metal silicide. Silicon dioxide is a preferred material for silicide block layers in analog circuits, as other materials such as silicon nitride and silicon oxy-nitride tend to trap charge, degrading performance of the analog circuits. The silicide block layer must be sufficiently robust to withstand deglaze etches and other wet etch processes. Robustness in the silicide block layer is commonly achieved by elevated deposition temperatures, 600° C. or higher, or correspondingly high temperatures in a densification process after deposition, for example, a furnace process at 650° C. for an hour. Such temperature regimens tend to cause diffusion of dopants in the NMOS and PMOS logic circuits, degrading performance factors such as off-state current. As smaller transistors are used in the logic circuits, this problem is exacerbated.

### SUMMARY

The present disclosure introduces a method of forming an integrated circuit having silicide block integrated with CMOS transistors. The sources, drains, and halo regions of the NMOS transistors and PMOS transistors are implanted with appropriate dopants. Prior to annealing the PMOS sources and drains, a silicide block layer, which includes primarily silicon dioxide and is free of silicon nitride and silicon oxy-nitride, is formed at less than 400° C. A subsequent spike anneal process concurrently anneals the PMOS sources and drains and densifies the silicide block layer. The spike anneal heats the PMOS sources and drains and the silicide block layer to greater than 1000° C. for at least 1 second and less than 10 seconds. The NMOS transistors have drain junctions with depths less than 120 nanometers. The NMOS transistors also have p-type halo regions containing boron adjacent to the drains. The NMOS transistors and PMOS transistors are laterally separated by a shallow trench isolation (STI) oxide layer. After patterning the silicide block layer, a wet deglaze process prepares the surfaces of the sources and drains for metal silicide formation. The wet deglaze removes less than 25 percent of the silicide block layer, and exposes the sides of the drains on the NMOS transistors less than 20 percent of the depth of the drain junction. The metal silicide on the drains of the NMOS transistors does not extend down sides of the drains, directly adjacent to the STI oxide layer, more than 20 percent of the depth of the drain junction.

### BRIEF DESCRIPTION OF THE VIEWS OF THE DRAWINGS

FIG. 1A through FIG. 1L are cross sections of an integrated circuit which includes an NMOS transistor, a PMOS transistor, and components with a suicide block layer, depicted in stages of an example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

An integrated circuit which includes an NMOS transistor, a PMOS transistor, and a component with a silicide block layer, may be formed by implanting the sources, drains, and halo regions of the NMOS transistor and the PMOS transistor with appropriate dopants. In particular, the halo regions of the NMOS transistor are implanted with boron. Prior to annealing the PMOS source and drain, a silicide block layer, which includes primarily silicon dioxide and is free of silicon nitride and silicon oxy-nitride, is formed at less than 400° C. A subsequent spike anneal process concurrently anneals the PMOS source and drain and densifies the silicide block layer. Densification of the silicide block layer reduces a hydrogen content in the silicide block layer and increases covalent bonding between silicon and oxygen in the silicide block layer. Densification of the silicide block layer is manifested as a reduction in etch rate of the silicide block layer in an aqueous solution of hydrofluoric acid. The spike anneal heats the PMOS source and drain and the silicide block layer to greater than 1000° C. for at least 1 second and less than 10 seconds. After patterning the silicide block layer, a wet deglaze process removes native oxide on surfaces of the sources and drains for metal silicide formation. The wet deglaze removes less than 25 percent of the silicide block layer, and exposes the side of the drain on the NMOS transistor to a depth that is less than 20 percent of the depth of the drain junction. A layer of metal is formed on the sources and drains and over the silicide block layer. The layer of metal is heated to react the metal with exposed silicon to form metal silicide. The metal silicide is not formed on silicon under the silicide block layer. Unreacted metal of the metal layer is subsequently removed.

The integrated circuit may also include a localized oxidation of silicon (LOCOS) oxide layer. The LOCOS oxide layer may be present in components of analog circuits, providing an oxide layer thinner than the STI oxide layer. Formation of the LOCOS oxide layer includes a wet etch process to remove a silicon dioxide layer; the wet etch process combined with the wet deglaze does not expose the side of the drain on the NMOS transistor more than 20 percent of the depth of the drain junction.

For the purposes of this disclosure, the term “instant top surface” of an integrated circuit is understood to refer to a top surface of the integrated circuit which exists at the particular step being disclosed. The instant top surface may change from step to step in the formation of the integrated circuit. For the purposes of this disclosure, the terms “lateral” and “laterally” are understood to refer to a direction parallel to a plane of the instant top surface of the integrated circuit.

It is noted that terms such as top, bottom, over, above, and under may be used in this disclosure. These terms should not be construed as limiting the position or orientation of a structure or element, but should be used to provide spatial relationship between structures or elements.

For the purposes of this disclosure, it will be understood that, if an element is referred to as being “adjacent” to another element, it may be directly adjacent to the other element, or intervening elements may be present. If an element is referred to as being “directly adjacent” to another element, it is understood there are no other intentionally disposed intervening elements present.

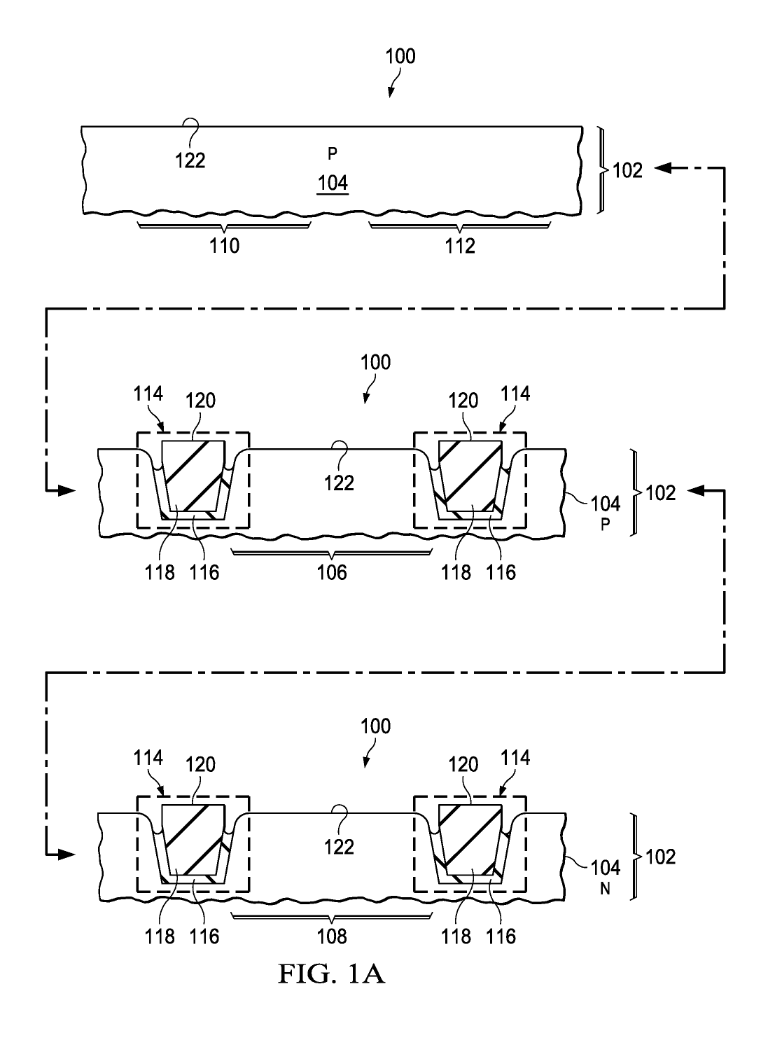

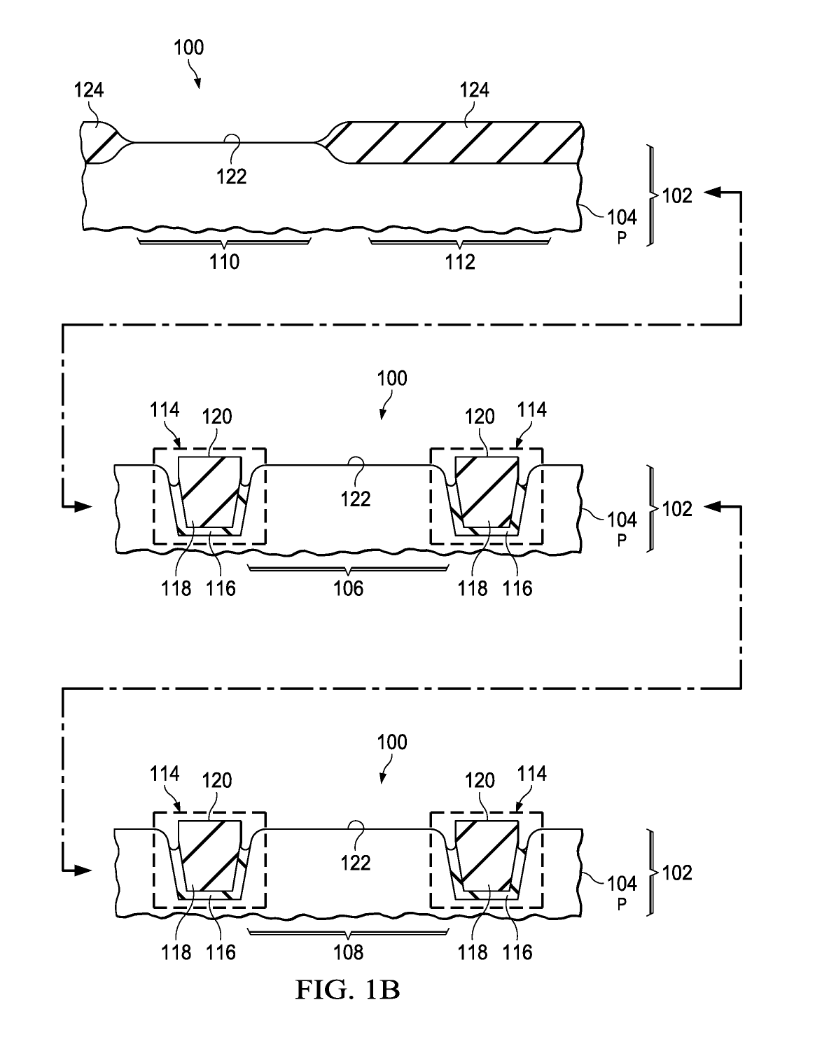

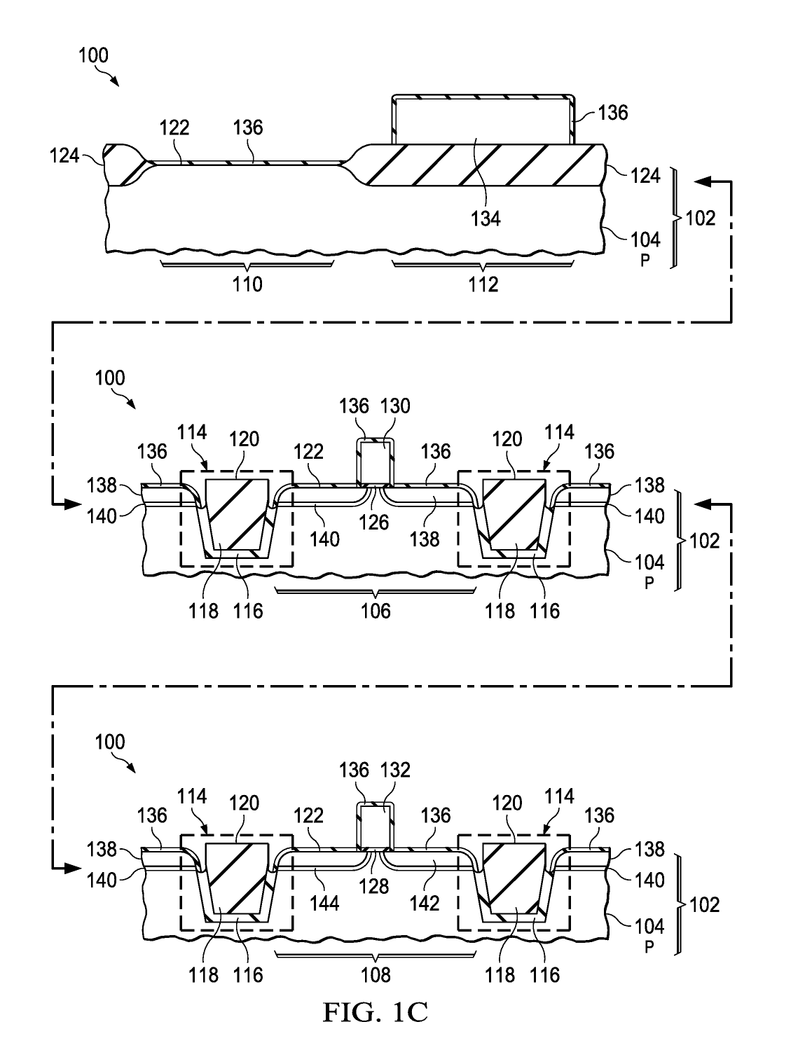

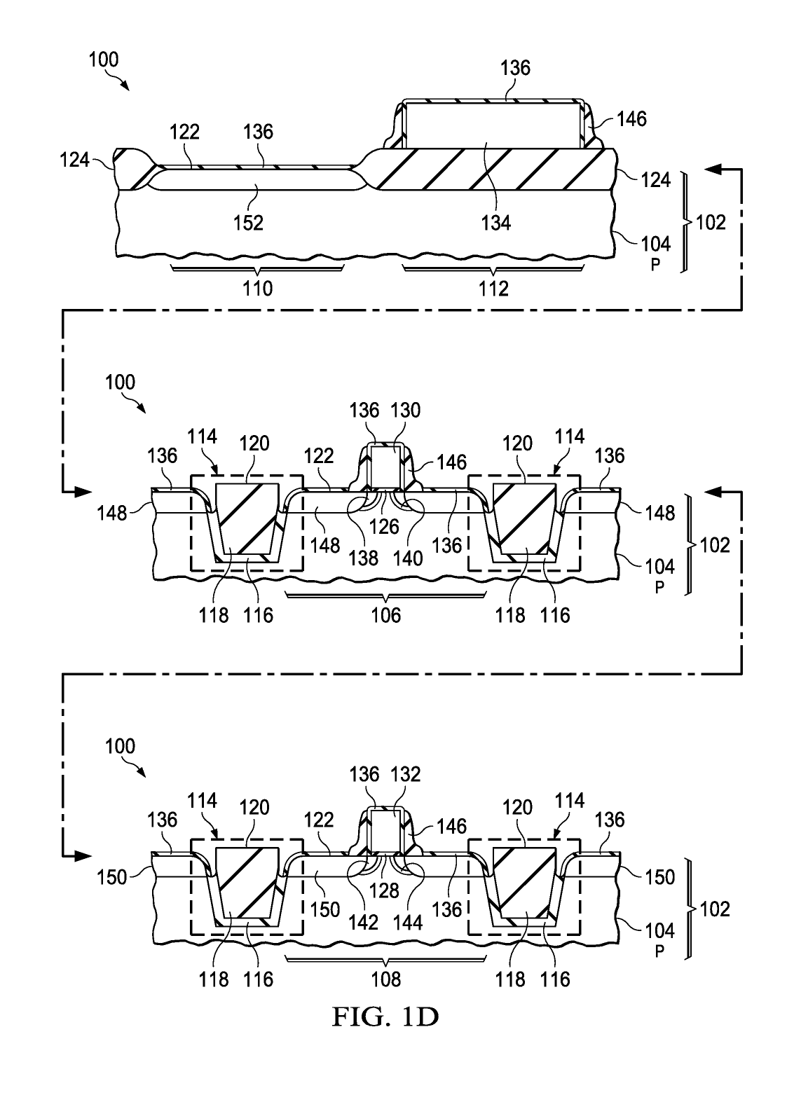

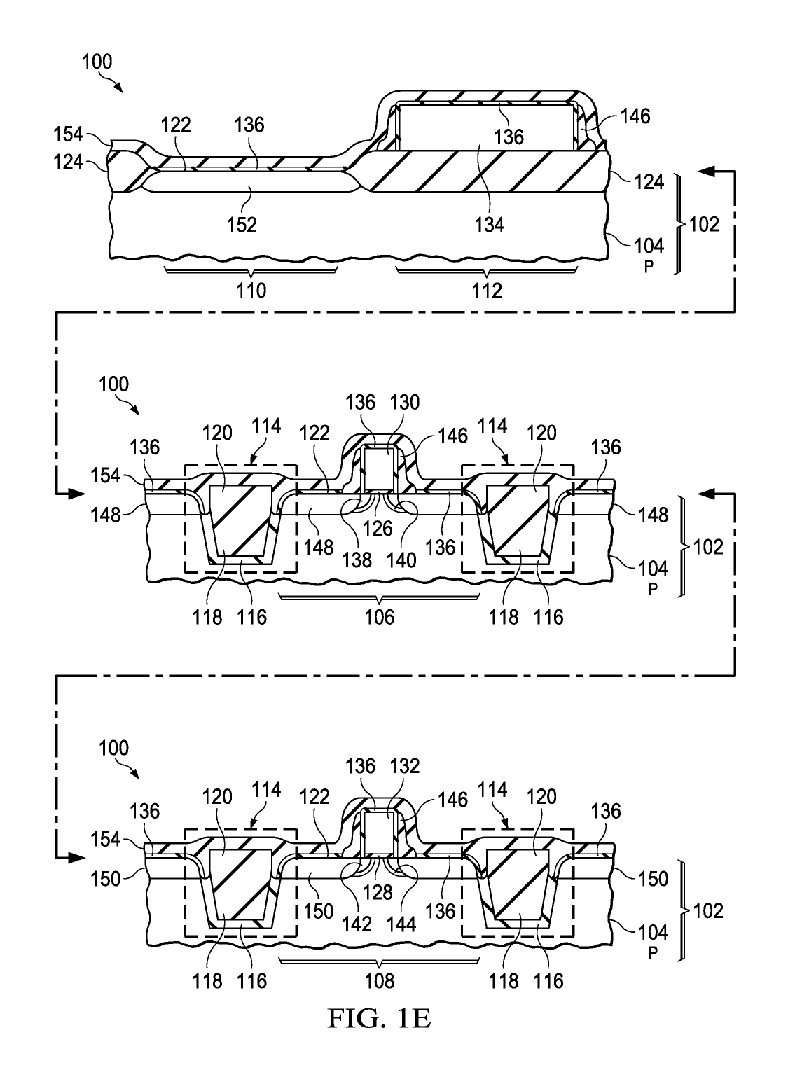

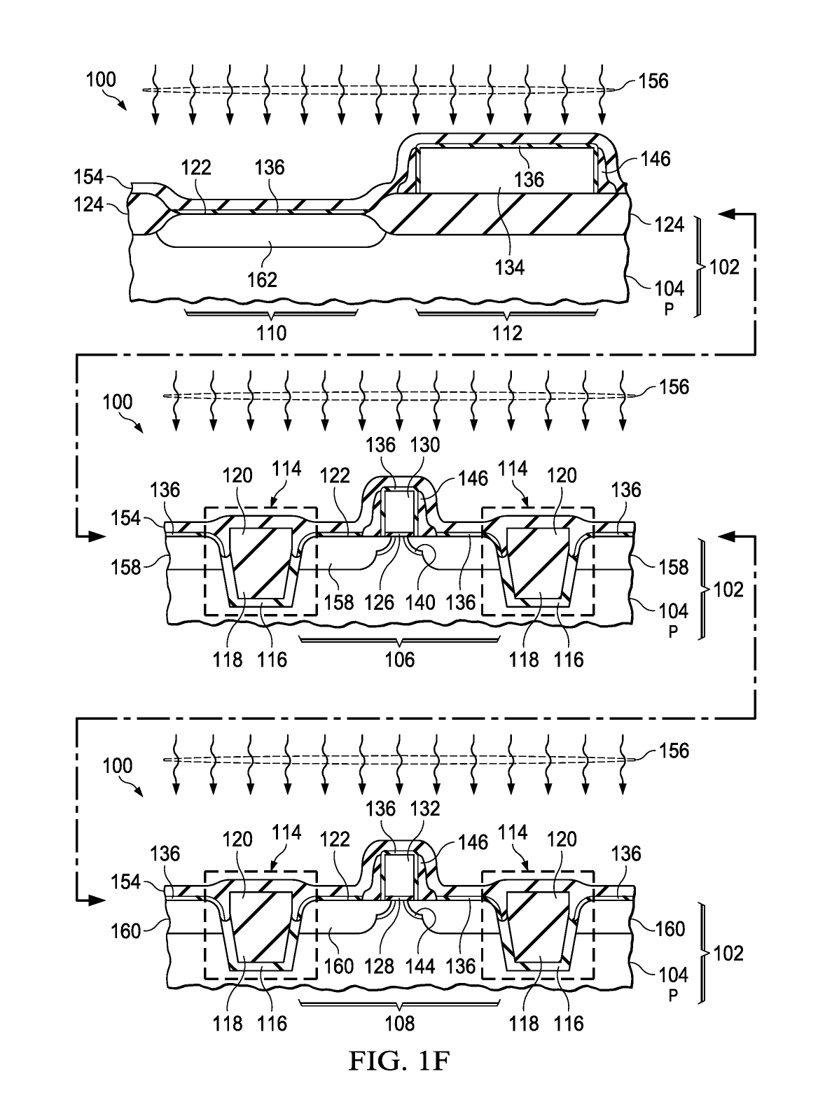

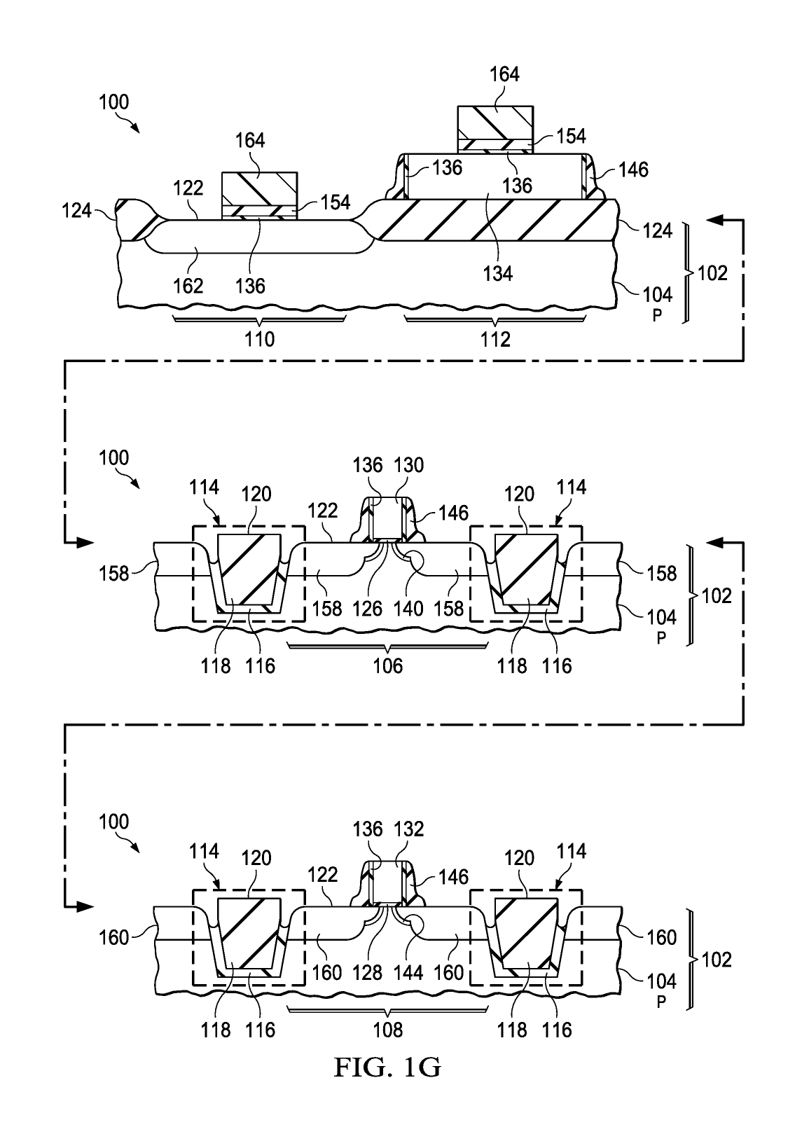

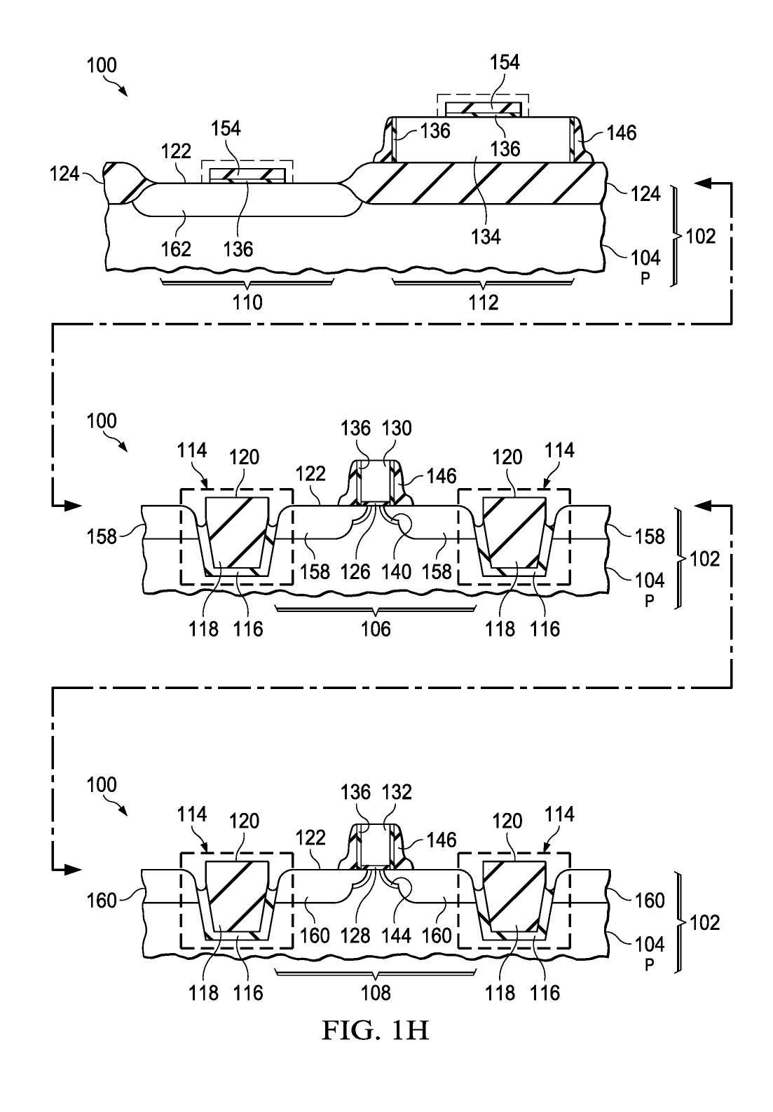

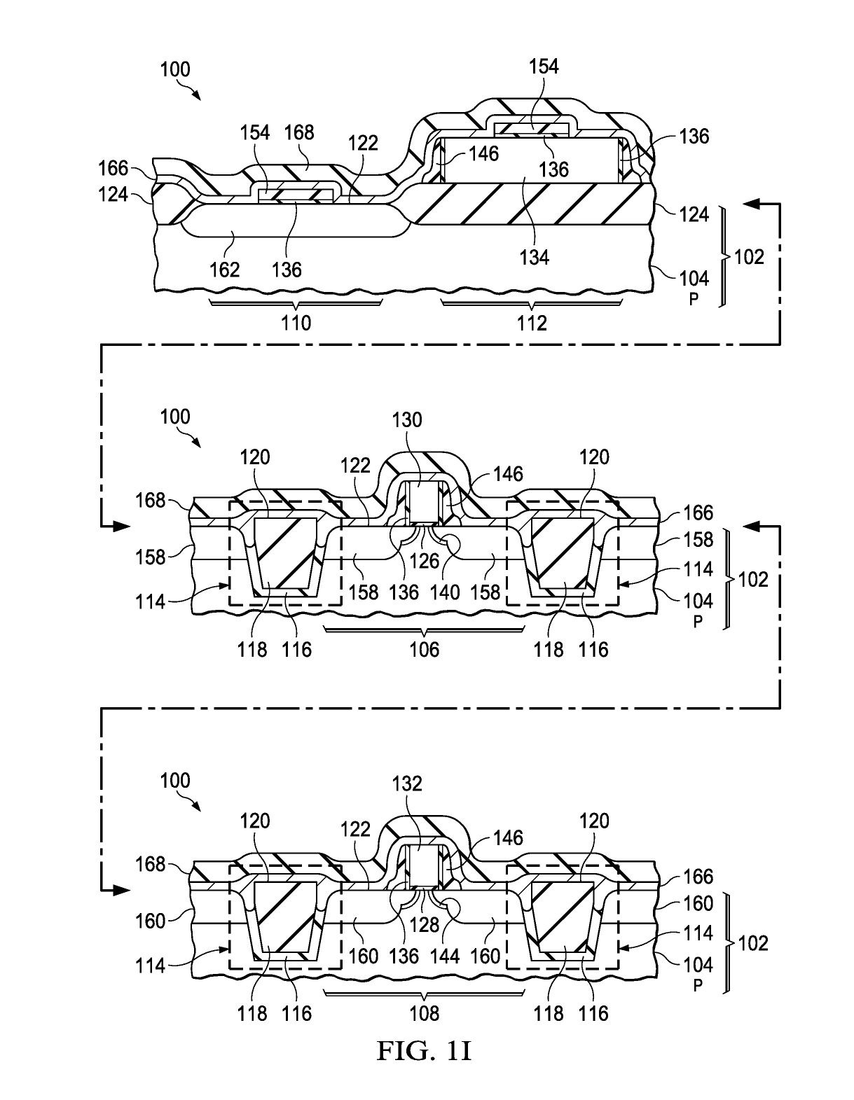

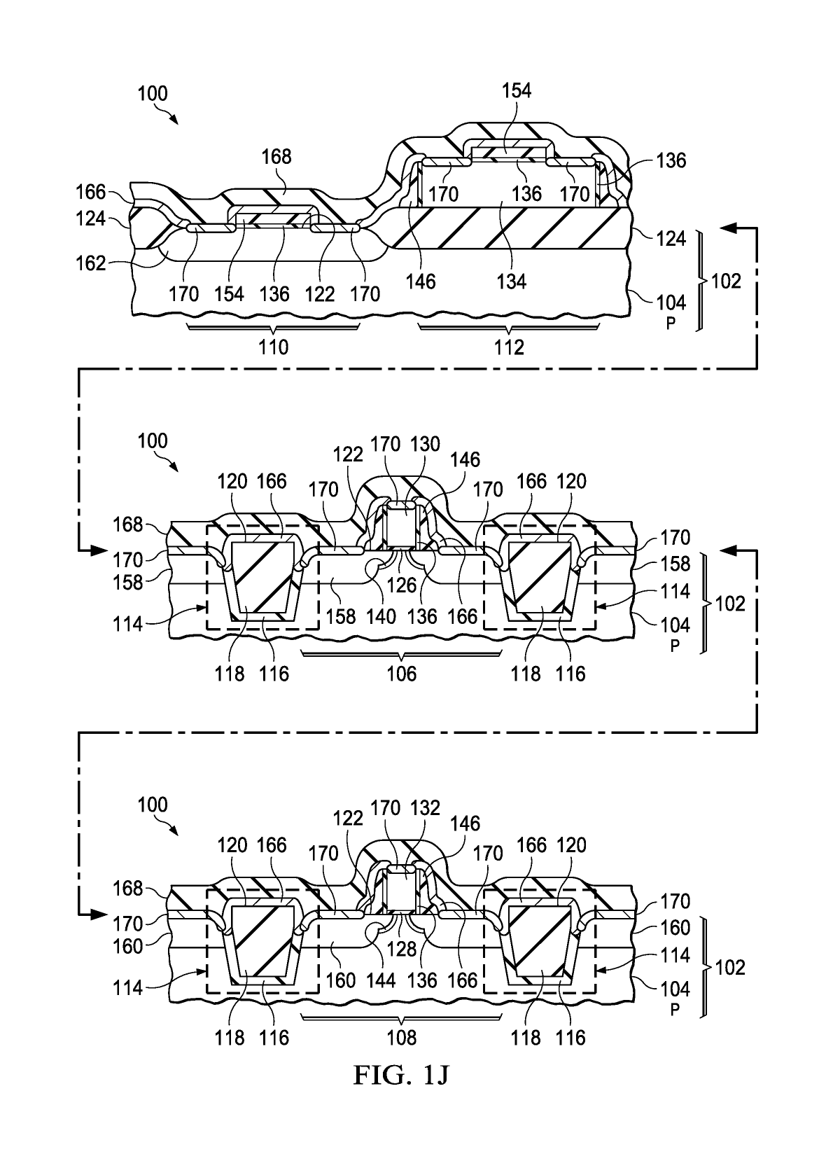

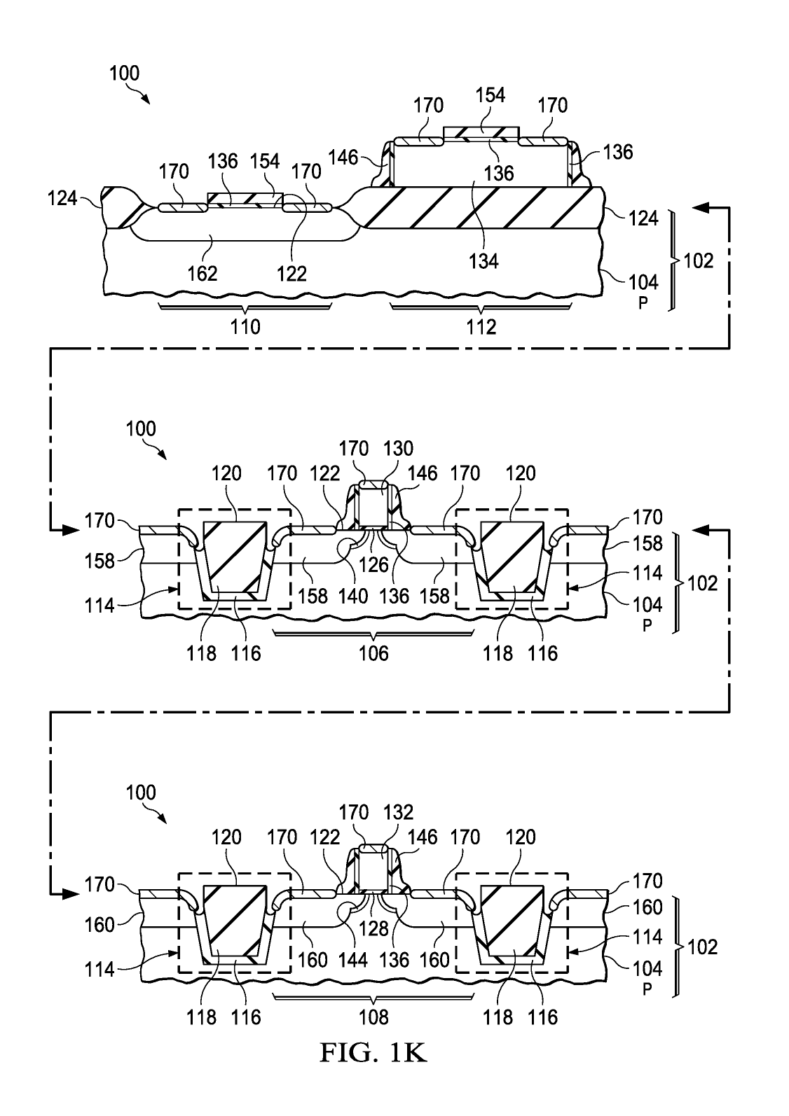

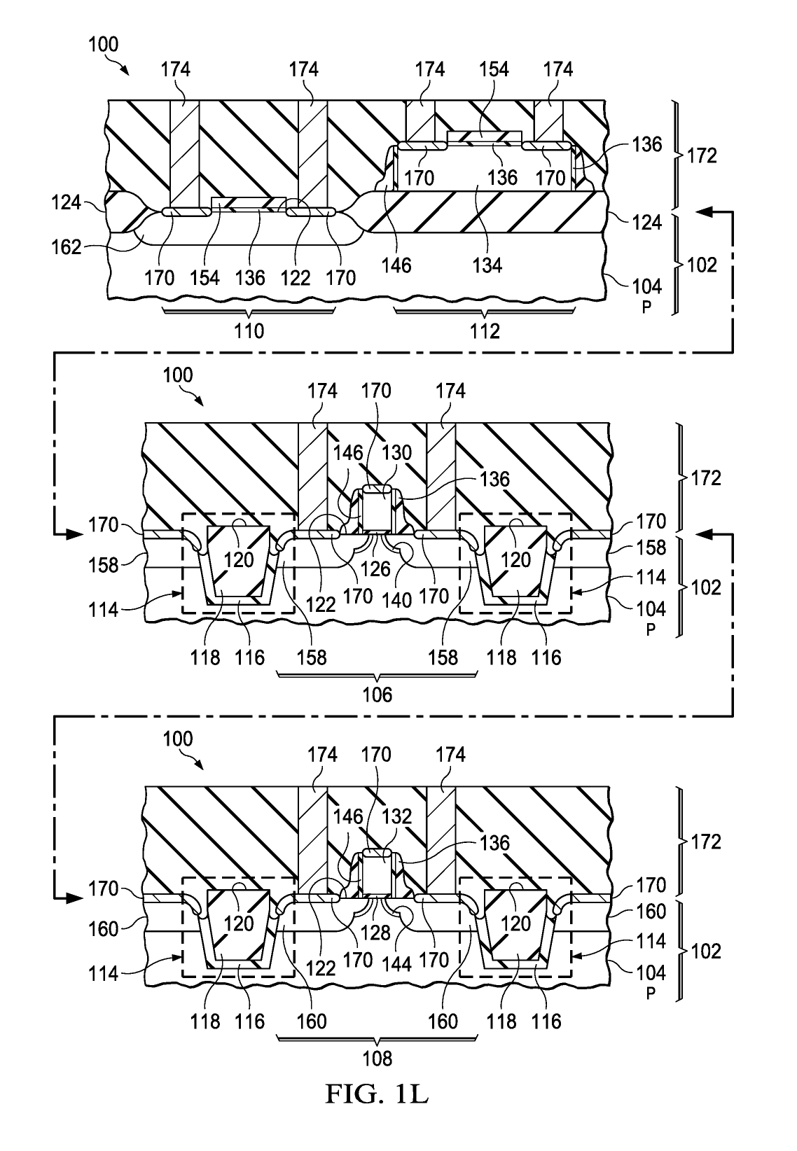

FIG. 1A through FIG. 1L are cross sections of an integrated circuit which includes an NMOS transistor, a PMOS transistor, and components with a silicide block layer, depicted in stages of an example method of formation. Referring to FIG. 1A, the integrated circuit 100 includes a substrate 102 with a semiconductor material 104. The substrate 102 may be, for example, a semiconductor wafer, such as a silicon wafer, a silicon-on-insulator (SOI) wafer, or a silicon wafer with a silicon epitaxial layer. The semiconductor material 104 includes silicon, and may be primarily silicon. In some regions, the semiconductor material 104 may be p-type, having p-type dopants such as boron. In other regions, the semiconductor material 104 may be n-type, having n-type dopants such as phosphorus. The integrated circuit 100 includes an area for the NMOS transistor 106, an area for the PMOS transistor 108, an area for a first component 110 having the silicide block layer, and an area for a second component 112 having the silicide block layer.

An STI oxide layer 114 is formed in isolation trenches in the substrate 102. An example process for forming the STI oxide layer 114 may include forming a chemical mechanical polish (CMP) stop layer of silicon nitride over the substrate 102, and etching the isolation trenches through the CMP stop layer and into the substrate 102. A thermal oxide liner 116 is formed on sidewalls and bottoms of the isolation trenches by a thermal oxidation process. Fill oxide 118 is formed on the thermal oxide liner 116 and over the CMP stop layer using a plasma enhanced chemical vapor deposition (PECVD) process using tetraethyl orthosilicate (TEOS), a high density plasma (HDP) process, a high aspect ratio process (HARP) using TEOS and ozone, an atmospheric chemical vapor deposition (APCVD) process using silane, or a sub-atmospheric chemical vapor deposition (SACVD) process using dichlorosilane. The fill oxide 118 is removed from over the CMP stop layer by an oxide CMP process, and the CMP stop layer is subsequently removed. A subsequent deglaze wet etch removes a portion of the thermal oxide liner 116 at edges of the substrate 102 directly adjacent to the STI oxide layer 114, as depicted in FIG. 1A, because the thermal oxide liner 116 has higher stress at those edges. The deglaze wet etch is performed so that the semiconductor material 104 is not exposed along a boundary with the STI oxide layer 114 more than 20 percent of a depth of a subsequently formed drain of the NMOS transistor 106. The drain of the NMOS transistor 106 is less than 120 nanometers deep in the semiconductor material 104.

A top surface 120 of the STI oxide layer 114 may be less than 10 nanometers higher than a top surface 122 of the semiconductor material 104 in the area for the NMOS transistor 106 and in the area for the PMOS transistor 108. Forming the STI oxide layer 114 so that the top surface 120 is less than 10 nanometers higher than the semiconductor material 104 may advantageously provide process latitude for forming gates of the NMOS transistor 106 and the PMOS transistor 108, as larger differences between the top surfaces 120 and 122 has been known to adversely affect a photolithographic process to form a gate mask and a reactive ion etch (RIE) process to form the gates.

Referring to FIG. 1B, a LOCOS oxide layer 124 is formed in the area for the second component 112. The LOCOS oxide layer 124 may be formed by forming a silicon nitride mask layer over a layer of pad oxide over the substrate 102. The silicon nitride mask layer is removed in areas for the LOCOS oxide layer 124, exposing the pad oxide. Silicon dioxide is formed in the areas exposed by the silicon nitride mask layer by thermal oxidation, to form the LOCOS oxide layer 124. The silicon nitride mask layer is subsequently removed. The pad oxide may be removed, using a wet etch process. The pad oxide is removed so that the semiconductor material 104 is not exposed along a boundary with the STI oxide layer 114 more than 20 percent of a depth of a subsequently formed drain of the NMOS transistor 106. The LOCOS oxide layer 124 may be significantly thinner than the STI oxide layer 114, for example, one third to one half as thick as the STI oxide layer 114, to provide field plate control for components with drift regions, not shown in FIG. 1B.

Referring to FIG. 1C, a NMOS gate dielectric layer 126 is formed on the semiconductor material 104 in the area for the NMOS transistor 106. A PMOS gate dielectric layer 128 is formed on the semiconductor material 104 in the area for the PMOS transistor 108. The PMOS gate dielectric layer 128 may have a different thickness and composition from the NMOS gate dielectric layer 126, to independently improve performances of the NMOS transistor 106 and the PMOS transistor 108.

A NMOS gate 130 is formed on the NMOS gate dielectric layer 126 in the area for the NMOS transistor 106. A PMOS gate 132 is formed on the PMOS gate dielectric layer 128 in the area for the PMOS transistor 108. The NMOS gate 130 and the PMOS gate 132 may have different structures and compositions, to independently improve performances of the NMOS transistor 106 and the PMOS transistor 108. A gate layer resistor 134 is formed on the LOCOS oxide layer 124 in the area for the second component 112. The NMOS gate 130, the PMOS gate 132, and the gate layer resistor 134 may include polycrystalline silicon, and at least a portion of the NMOS gate 130, the PMOS gate 132, and the gate layer resistor 134 may be formed concurrently. The NMOS gate 130 and the PMOS gate 132 may be formed, for example, by forming a layer of gate material such as polycrystalline silicon over the substrate 102, the STI oxide layer 114, and the LOCOS oxide layer 124. A thickness of the layer of gate material in the areas for the NMOS transistor 106 and the PMOS transistor 108 may be affected by the height of the top surface 120 of the STI oxide layer 114 adjacent to the areas for the NMOS transistor 106 and the PMOS transistor 108 relative to the top surface 122 of the substrate 102, in that variations in the height of the top surface 120 of the STI oxide layer 114 may produce corresponding variations in the thickness of the layer of gate material. A layer of photoresist may be formed over the layer of gate material, along with anti-reflection layers and hard mask layers. The thicknesses of the photoresist, anti-reflection layers, and hard mask layers are similarly adversely affected by variations in the height of the top surface 120 of the STI oxide layer 114 relative to the top surface 122 of the substrate 102. The photoresist is patterned by a photolithographic process to form a gate mask. A physical linewidth of the gate mask in the areas for the NMOS gate 130 and the PMOS gate 132 may be affected by the thicknesses of the photoresist, anti-reflection layers, and hard mask layers. Thicker photoresist may produce larger physical linewidths of the gate mask, and vice versa. Subsequently, an RIE process is used to etch the layer of gate material where exposed by the gate mask to form the NMOS gate 130, the PMOS gate 132, and the gate layer resistor 134. Physical linewidths of the NMOS gate 130 and the PMOS gate 132 may be affected by the physical linewidth of the gate mask, as well as by the thickness of the layer of gate material. Thicker material may produce larger linewidths of the gates 130 and 132, and vice versa. Thus, maintaining the top surface 120 of the STI oxide layer 114 within 10 nanometers of the top surface 122 of the substrate 102 may advantageously produce consistent physical linewidths of the gates 130 and 132, sometimes referred to as physical gate lengths.

A silicon dioxide layer 136 is formed on the gates 130 and 132 and the gate layer resistor 134, and may extend onto the top surface 122 of the semiconductor material 104 where exposed, for example in the area for the first component 110. The silicon dioxide layer 136 may be formed by a thermal oxidation process, or by a conformal PECVD process.

N-type source and drain extensions 138 are formed in the semiconductor material 104 in the area for the NMOS transistor 106. The n-type source and drain extensions 138 extend partway under the NMOS gate 130, as depicted in FIG. 1C. The n-type source and drain extensions 138 may be formed by implanting n-type dopants such as phosphorus, arsenic, and antimony into the semiconductor material 104 using the NMOS gate 130 to block the n-type dopants. P-type halo regions 140 are formed in the semiconductor material 104 under the NMOS gate 130 directly adjacent to the n-type source and drain extensions 138. The p-type halo regions 140 may be formed by implanting p-type dopants such as boron at tilt angles of 15 degrees to 30 degrees, to place the implanted p-type dopants past the n-type source and drain extensions 138. The substrate 102 is annealed after implanting, to activate the implanted dopants. The p-type halo regions 140 may extend under the n-type source and drain extensions 138, as depicted in FIG. 1C.

P-type source and drain extensions 142 and n-type halo regions 144 are formed in the semiconductor material 104 in the area for the PMOS transistor 108, by a similar process sequence. Boron may be implanted to form the p-type source and drain extensions 142, and phosphorus may be implanted to form the n-type halo regions 144.

The silicon dioxide layer 136 may optionally be augmented by additional layers of dielectric material between forming the n-type source and drain extensions 138 and the p-type source and drain extensions 142. Additional elements, such as carbon, may be implanted during formation of the n-type source and drain extensions 138 and the p-type source and drain extensions 142 to control diffusion of the implanted dopants.

Referring to FIG. 1D, gate sidewall spacers 146 are formed on lateral surfaces of the NMOS gate 130, the PMOS gate 132, and the gate layer resistor 134. The gate sidewall spacers 146 may include one or more layers of dielectric material such as silicon nitride and silicon dioxide. The gate sidewall spacers 146 on the NMOS gate 130 may have a different structure and lateral width than the gate sidewall spacers 146 on the PMOS gate 132, to independently improve performances of the NMOS transistor 106 and the PMOS transistor 108.

N-type dopants such as phosphorus and arsenic are implanted into the semiconductor material 104 in the area for the NMOS transistor 106 to form NMOS source and drain implanted regions 148, extending partway under the gate sidewall spacers 146, and partly overlapping the n-type source and drain extensions 138. The n-type dopants may be implanted with a dose greater than 1×10¹⁵ cm⁻² to attain low resistance in the source and drain of the NMOS transistor 106.

P-type dopants such as boron are implanted into the semiconductor material 104 in the area for the PMOS transistor 108 to form PMOS source and drain implanted regions 150, extending partway under the gate sidewall spacers 146, and partly overlapping the p-type source and drain extensions 142. The p-type dopants may be implanted with a dose greater than 3×10¹⁵ cm⁻² to attain low resistance in the source and drain of the PMOS transistor 108.

N-type dopants are also implanted into the semiconductor material 104 in the area for the first component 110 to form a resistor implanted region 152. The resistor implanted region 152 may optionally be formed concurrently with the NMOS source and drain implanted regions 148.

Referring to FIG. 1E, a silicide block layer 154 is formed over the instant top surface of the integrated circuit 100. The silicide block layer 154 includes primarily silicon dioxide, and is free of silicon nitride and silicon oxy-nitride, which may advantageously reduce trapped charge in the silicide block layer 154. In one version of the instant example, the silicide block layer 154 may consist essentially of silicon dioxide. The silicide block layer 154 may be, for example, 20 nanometers to 45 nanometers thick. The silicide block layer 154 is formed at a temperature less than 400° C. The silicide block layer 154 may be formed, for example, by a PECVD process using silane and oxygen. The silicide block layer 154 is formed before annealing the NMOS source and drain implanted regions 148 and the PMOS source and drain implanted regions 150.

Referring to FIG. 1F, a spike anneal process 156 concurrently anneals the NMOS source and drain implanted regions 148 and the PMOS source and drain implanted regions 150 of FIG. 1E to form NMOS source and drain regions 158 and PMOS source and drain regions 160, respectively, anneals the resistor implanted region 152 of FIG. 1F to form an n-type diffused resistor 162, and densifies the silicide block layer 154. The NMOS source and drain regions 158 include the n-type source and drain extensions 138 of FIG. 1E. Similarly, the PMOS source and drain regions 160 include the p-type source and drain extensions 142.

The spike anneal process 156 may be performed in a rapid thermal processor (RTP) tool. The spike anneal process 156 heats the NMOS source and drain implanted regions 148, the PMOS source and drain implanted regions 150, and the silicide block layer 154 to a temperature greater than 1000° C. for more than 1 second, but less than 10 seconds. Moreover, the spike anneal process 156 heats the NMOS source and drain implanted regions 148, the PMOS source and drain implanted regions 150, and the silicide block layer 154 to a temperature greater than 900° C. for no more than 30 seconds. The spike anneal process 156 may be extended to a flash anneal process, which heats the NMOS source and drain implanted regions 148, the PMOS source and drain implanted regions 150, and the silicide block layer 154 to a temperature greater than 1200° C. for a time period of microseconds to milliseconds. The spike anneal process 156 may be distinguished from a rapid thermal anneal process which heats to a temperature of 800° C. to 1000° C. for a time period greater than 10 seconds. The spike anneal process 156 may also be distinguished from a furnace process which heats for a time period of minutes to hours. The spike anneal process 156 may advantageously anneal the NMOS source and drain implanted regions 148 and the PMOS source and drain implanted regions 150 with less diffusion of the boron dopants in the p-type halo regions 140 compared to an anneal process having a longer time scale, such as a rapid thermal anneal process or a furnace anneal process. Concurrently annealing the NMOS source and drain implanted regions 148 and the PMOS source and drain implanted regions 150, and densifying the silicide block layer 154 may advantageously reduce diffusion of the boron dopants in the p-type halo regions 140 compared to using separate anneal and densification processes. The spike anneal process 156 may advantageously reduce boron diffusion from the PMOS source and drain implanted regions 150 into the silicon dioxide layer 136 in the area for the PMOS transistor 108, compared to an anneal with a longer time frame or to using separate anneal and densification processes. Boron in the silicon dioxide layer 136 affects an etch rate during a subsequent etch process to pattern the silicide block layer 154, causing overetch in the area for the NMOS transistor 106.

Referring to FIG. 1G, a silicide block mask 164 is formed over the silicide block layer 154, covering areas in which metal silicide is to be blocked, that is, prevented from forming. In the instant example, the silicide block mask 164 is formed over an area for a resistor body of the n-type diffused resistor 162, and over an area for a resistor body of the gate layer resistor 134.

The silicide block layer 154 and the silicon dioxide layer 136 are removed where exposed by the silicide block mask 164. The silicide block layer 154 and the silicon dioxide layer 136 may be removed by an RIE process, stopping on the semiconductor material 104 and the gate layer resistor 134. Using the spike anneal process 156 of FIG. 1F to reduce boron diffusion into the silicon dioxide layer 136 in the area for the PMOS transistor 108 may advantageously enable a more uniform removal of the silicon dioxide layer 136 in the areas for the NMOS transistor 106 and the PMOS transistor 108, reducing overetch and damage to the top surface 122 of the semiconductor material 104 in the area for the NMOS transistor 106.

The silicide block mask 164 is subsequently removed, for example, with an oxygen plasma process, which forms a native oxide on the top surface 122 of the semiconductor material 104. Removal of the silicide block mask 164 forms a thicker native oxide on more damaged silicon, requiring a longer deglaze to prepare the silicon for subsequent formation of metal silicide. Thus, using the spike anneal process 156 may reduce the thickness of the native oxide.

Referring to FIG. 1H, a wet deglaze process is performed which removes the native oxide from the top surface 122 of the semiconductor material 104 in preparation for formation of a metal layer on the top surface 122. The wet deglaze process may include, for example, a wet etch using an aqueous solution of dilute hydrofluoric acid, for example, 0.5 percent to 1 percent hydrofluoric acid, for 20 seconds to 40 seconds. The wet deglaze process may remove 20 percent to 25 percent of the thickness of the silicide block layer 154, as indicated in FIG. 1H. The wet deglaze process removes some of the thermal oxide liner 116 in the STI oxide layer 114, exposing more of sides of the NMOS source and drain regions 158 abutting the STI oxide layer 114. Using the spike anneal process 156 of FIG. 1F enables a shorter wet deglaze process to prepare the top surface 122 and thus advantageously reduces exposure of the sides of the NMOS source and drain regions 158.

Referring to FIG. 1I, a metal layer 166 is formed over the integrated circuit 100. The metal layer 166 may include, for example, platinum, cobalt, or nickel. The metal layer 166 contacts the NMOS source and drain regions 158, the PMOS source and drain regions 160, the gate layer resistor 134 where exposed by the silicide block layer 154, and the n-type diffused resistor 162 where exposed by the silicide block layer 154. An optional barrier layer 168 may be formed over the metal layer 166. The barrier layer 168 may include, for example, titanium nitride or tantalum nitride.

Referring to FIG. 1J, the metal layer 166 and the integrated circuit 100 are heated to react the metal layer 166 with silicon in the NMOS source and drain regions 158, the PMOS source and drain regions 160, the gate layer resistor 134, and the n-type diffused resistor 162 to form metal silicide 170. The metal layer 166 and the integrated circuit 100 may be heated in an RTP tool, for example. The temperature necessary to react the metal layer 166 with the silicon depends on the composition of the metal layer 166, and the desired stoichiometry of the metal silicide 170. The barrier layer 168 may improve stoichiometry and uniformity of the metal silicide 170.

The metal silicide 170 forms on exposed surfaces of the NMOS source and drain regions 158. By using the spike anneal process 156 of FIG. 1F, the wet deglaze process described in reference to FIG. 1H may be limited, so that the portion of the sides of exposed NMOS source and drain regions 158 that are exposed to the metal layer 166 may be limited, so that the metal silicide 170 extends down the sides of the NMOS source and drain regions 158 a distance that is less than 20 percent of a depth of the junction of the NMOS source and drain regions 158. Limiting the metal silicide 170 on the sides of the NMOS source and drain regions 158 may advantageously reduce junction leakage in the NMOS source and drain regions 158 during operation of the integrated circuit 100.

Referring to FIG. 1K, the barrier layer 168 of FIG. 1J, if present, is removed. The metal layer 166 of FIG. 1J which remains after forming the metal silicide 170 is also removed, leaving the metal silicide 170 in place. The barrier layer 168 and the metal layer 166 may be removed by a wet etch process. To remove platinum, the wet etch process may include, for example, aqua regia. To remove cobalt or nickel, the wet etch process may include, for example, an aqueous mixture of sulfuric acid and hydrogen peroxide.

Referring to FIG. 1L, a pre-metal dielectric (PMD) layer 172 is formed on the integrated circuit 100. The PMD layer 172 may include one or more sub-layers of dielectric material, for example a PMD liner of silicon nitride, a layer of silicon dioxide-based material formed by a high density plasma or a chemical vapor deposition (CVD) process using TEOS and ozone, a layer of silicon dioxide-based material such as phosphorus silicate glass (PSG) or boron phosphorus silicate glass (BPSG), and a cap layer of silicon nitride, silicon oxynitride, silicon carbide or silicon carbide nitride.

Contacts 174 are formed through the PMD layer 172 to make electrical connections to the metal silicide 170. The contacts 174 may be formed by etching contact holes through the PMD layer 172, and forming a titanium liner, by sputtering or an ionized metal plasma (IMP) process, on the PMD layer 172 and extending into the contact holes. A titanium nitride liner is formed, by reactive sputtering or atomic layer deposition (ALD), on the titanium liner. A layer of tungsten is formed, by a metal organic chemical vapor deposition (MOCVD) process, on the titanium nitride liner, filling the contact holes. The tungsten, titanium nitride and titanium are removed from over a top surface of the PMD layer 172 by a tungsten CMP process, leaving the tungsten fill metal, titanium nitride liner and titanium liner in the contact holes to provide the contacts 174.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A method of forming an integrated circuit, comprising:
providing a substrate including a semiconductor material, the semiconductor material including silicon;
implanting boron into the semiconductor material in areas for p-channel metal oxide semiconductor (PMOS) source and drain regions of a PMOS transistor;
implanting boron into the semiconductor material in areas for p-type halo regions of an n-channel metal oxide semiconductor (NMOS) transistor;
forming a silicide block layer over the substrate at a temperature less than 400° C., the silicide block layer including primarily silicon dioxide and being free of silicon nitride and silicon oxy-nitride;
concurrently annealing the PMOS source and drain regions and densifying the silicide block layer;
patterning the silicide block layer so that the PMOS source and drain regions are exposed and NMOS source and drain regions of the NMOS transistor are exposed;
performing a wet deglaze process which removes native oxide from the PMOS source and drain regions and from the NMOS source and drain regions, the wet deglaze process removing less than 25 percent of the silicide block layer; and
forming metal silicide on the semiconductor material where exposed by the silicide block layer, including on the PMOS source and drain regions and on the NMOS source and drain regions.

2. The method of claim 1, wherein the silicide block layer is formed by a plasma enhanced chemical vapor deposition (PECVD) process using silane.

3. The method of claim 1, wherein the silicide block layer is 20 nanometers to 45 nanometers thick, prior to concurrently annealing the PMOS source and drain regions and densifying the silicide block layer.

4. The method of claim 1, wherein concurrently annealing the PMOS source and drain regions and densifying the silicide block layer includes heating the substrate to greater than 1000° C. for at least 1 second and less than 10 seconds.

5. The method of claim 1, wherein concurrently annealing the PMOS source and drain regions and densifying the silicide block layer is performed in a rapid thermal processor (RTP) tool.

6. The method of claim 1, wherein the substrate remains below 400° C. between forming the silicide block layer and concurrently annealing the PMOS source and drain regions and densifying the silicide block layer.

7. The method of claim 1, wherein the silicide block layer consists essentially of silicon dioxide after concurrently annealing the PMOS source and drain regions and densifying the silicide block layer.

8. The method of claim 1, wherein patterning the silicide block layer includes a plasma etch process.

9. The method of claim 1, further comprising forming a shallow trench isolation (STI) oxide layer directly adjacent to the NMOS transistor.

10. The method of claim 9, wherein the metal silicide extends down a side of the NMOS drain region directly adjacent to the STI oxide layer less than 20 percent of a junction depth of the NMOS drain region.

11. The method of claim 9, wherein the junction depth of the NMOS drain region is less than 120 nanometers.

12. The method of claim 1, wherein the metal silicide includes an element selected from the group consisting of platinum, cobalt, and nickel.

13. The method of claim 1, further comprising forming a local oxidation of silicon (LOCOS) oxide layer on the semiconductor material.

14. The method of claim 1, wherein the wet deglaze process includes a wet etch using an aqueous solution of dilute hydrofluoric acid.

15. The method of claim 1, wherein implanting boron into the semiconductor material in areas for the PMOS source and drain regions includes implanting boron at a dose greater than 3×10¹⁵ cm⁻².

16. An integrated circuit, comprising:
a substrate including a semiconductor material, the semiconductor material including silicon;
a PMOS transistor in the semiconductor material, the PMOS transistor including PMOS source and drain regions having boron dopants;
an NMOS transistor in the semiconductor material, the NMOS transistor including p-type halo regions directly adjacent to NMOS source and drain regions of the NMOS transistor;
an STI oxide layer on the semiconductor material, the STI oxide layer being directly adjacent to the NMOS drain region;
a silicide block layer over the substrate, the silicide block layer including primarily silicon dioxide and being free of silicon nitride and silicon oxy-nitride; and
metal silicide on the semiconductor material where exposed by the silicide block layer, the metal silicide extending down a side of the NMOS drain region directly adjacent to the STI oxide layer less than 20 percent of a junction depth of the NMOS drain region.

17. The integrated circuit of claim 16, further comprising a LOCOS oxide layer on the semiconductor material.

18. The integrated circuit of claim 16, wherein the junction depth of the NMOS drain region is less than 120 nanometers.

19. The integrated circuit of claim 16, wherein the metal silicide includes an element selected from the group consisting of platinum, cobalt, and nickel.

20. The integrated circuit of claim 16, wherein the silicide block layer consists essentially of silicon dioxide.
